(19) United States
(12) Patent Application Publication
(10) Pub. No.: US 2019/0368027 A1
(43) Pub. Date: Dec. 5, 2019

(54) MANUFACTURING METHOD OF SUBSTRATE WITH TRANSPARENT CONDUCTIVE FILM, MANUFACTURING APPARATUS OF SUBSTRATE WITH TRANSPARENT CONDUCTIVE FILM, AND TRANSPARENT CONDUCTIVE FILM

(71) Applicant: ULVAC, INC., Chigasaki-shi (JP)

(72) Inventors: Yukiaki OONO, Chigasaki-shi (JP); Hirohisa TAKAHASHI, Chigasaki-shi (JP); Masanori SHIRAI, Chigasaki-shi (JP); Motoshi KOBAYASHI, Chigasaki-shi (JP)

(21) Appl. No.: 16/276,892

(22) Filed: Feb. 15, 2019

Related U.S. Application Data
(63) Continuation of application No. PCT/JP2017/032929, filed on Sep. 12, 2017.

(30) Foreign Application Priority Data
Sep. 12, 2016 (JP) 2016-177966

(51) Int. Cl. C23C 14/08; C23C 14/34; C23C 14/58; C23C 14/02; G06F 3/044; G06F 3/041

(52) U.S. Cl. CPC C23C 14/086; C23C 14/34; C23C 14/5806; G06F 2203/04103; G06F 3/044; G06F 3/0414; C23C 14/02

(57) ABSTRACT

A substrate with a transparent conductive film of the invention is a substrate with a transparent conductive film such that a transparent conductive film is disposed to be in contact with an insulating transparent substrate. The transparent conductive film includes: a crystal nucleus that is generated in a surface layer portion of the transparent conductive film; a crystal portion that is formed by growth from the crystal nucleus positioned in the surface layer portion and encloses the crystal nucleus; and a crystal grain boundary that is formed between crystal portions due to the crystal portions located at adjacent positions growing until colliding with each other. The crystal nucleus remains in the surface layer portion in each of the crystal portions.

### CROSS REFERENCE TO RELATED APPLICATIONS

This is a Continuation Application of International Application No. PCT/JP2017/032929, filed on Sep. 12, 2017, which claims priority to Japanese Patent Application No. 2016-177966, filed in Japan on Sep. 12, 2016. The contents of the aforementioned applications are incorporated herein by reference.

### BACKGROUND OF THE INVENTION

### Field of the Invention

The present invention relates to a manufacturing method of a substrate with a transparent conductive film, a manufacturing apparatus of a substrate with a transparent conductive film, and a substrate with a transparent conductive film, which is capable of obtaining excellent electrical characteristics under a manufacturing condition of a low-temperature process.

### Description of the Related Art

A touch panel (also referred to as a touch sensor) is a constituent element of an input device that can input data by detecting a position touched by an operator touching a transparent surface on a display screen with a finger or a pen and can realize direct and intuitive input rather than key input. For this reason, in recent years, touch panels have been frequently used for operation units of various types of electronic equipment including mobile phones, mobile information terminals represented by smartphones, car navigation systems, various types of game machines, and the like.

The touch panels can be used as an input device by being laminated on a display screen of a flat type display such as liquid phase panels or organic electroluminescence (organic EL) panels. There are various types among detection types of the touch panel such as resistance types, capacitance types, ultrasonic types, or optical types, and structures thereof are diverse. Of these, in recent years, capacitance types have become mainstream in touch panels for smartphone applications.

In touch panels for smartphone applications, “reducing weight,” “thinning,” and “high performance” are required as market needs. Of these, a device structure called on-cell (On-Cell) or in-cell (In-Cell) in which a touch sensor function is incorporated in a display is employed for “reducing weight” and “thinning.”

In a touch panel type called On-Cell, a transparent conductive film such as indium tin oxide (ITO) is disposed as a sensor electrode on a back surface of a substrate (also called a color filter (CF) substrate) on a color filter side. A structure in which a transparent conductive film is provided on a back surface of a CF substrate is conventionally known as a transparent conductive substrate and has been widely used in fields other than touch panels for smartphone applications (display with an embedded touch function), for example, solar cells, various types of displays, or the like. Here, ITO is indium tin oxide (Indium Tin Oxide).

When a touch panel is mounted on a display in smartphone applications, an adhesive is used for bonding a substrate on a color filter side (CF substrate) and a substrate on a thin film transistor (TFT) side (also referred to as a TFT substrate). Therefore, restrictions are imposed on a temperature at the time of forming a touch sensor (temperature at the time of deposition, post-heating, or the like) (for example, refer to Japanese Unexamined Patent Application, First Publication No. 2009-283149).

Films having lower heat resistance than glass are used for touch sensors called GFF (cover glass+two sheets of single-sided ITO film) and GF2 (of which there are two types including a double-sided ITO (DITO) type in which ITO film is formed on both sides of a base film and an ITO bridge type in which ITO is overlaid in two layers on one side of a base film), which are currently drawing attention as a structure of touch panels. For example, in the case of the GFF, thinning has been advanced at present, and a configuration in which an ITO film is provided on a polyethylene terephthalate (PET) film has been studied.

In order to manufacture such an ITO film functioning as a sensor electrode of a capacitance type, a pass-through type sputtering method with high productivity in which an ITO-based material is mainly used as a target is employed. However, in manufacturing the conventional ITO film, a high temperature process at 200° C. or higher has been mainstream at the time of deposition (for example, refer to S. Ishibashi et al, J. Vac. Sci. Technol. A., 8, (3), 1403 (1990)), and it is extremely difficult to obtain excellent electrical characteristics in a low-temperature process of 100° C. or lower which is suitable for PET film or the like.

From such a background, development of a manufacturing method of an ITO film with low resistance using a low-temperature process has been expected in a manufacturing method of an ITO film using a pass-through type sputtering method.

### SUMMARY OF THE INVENTION

The invention has been devised in consideration of such conventional circumstances, and it is an object of the invention to provide a manufacturing method and a manufacturing apparatus in which a substrate with a transparent conductive film with low resistance can be formed using a low-temperature process.

A manufacturing method of a substrate with a transparent conductive film according to a first aspect of the invention is a manufacturing method of a substrate with a transparent conductive film such that a transparent conductive film is disposed to be in contact with an insulating transparent substrate and includes, in order, at least a step α of controlling the transparent substrate to have a predetermined pre-deposition temperature in a heat treatment space with a desired reduced-pressure atmosphere, a step β of applying a sputtering voltage to a target forming a base material of the transparent conductive film to perform sputtering to deposit the transparent conductive film on the transparent substrate having the predetermined temperature in a deposition space with a desired process gas atmosphere, and a step α of performing a post-heat treatment on the transparent conductive film formed on the transparent substrate in an air atmosphere, wherein the pre-deposition temperature in step α is zero degree or lower.

In the manufacturing method of the substrate with a transparent conductive film according to the first aspect of the invention, a partial pressure of water occupying the process gas atmosphere is preferably 1×10⁻³ Pa or less in step β.

In the manufacturing method of the substrate with a transparent conductive film according to the first aspect of the invention, it is preferable to control sputtering conditions such that a temperature after deposition of the transparent substrate having the transparent conductive film formed thereon is lower than 29° C. in step β.

In the manufacturing method of the substrate with a transparent conductive film according to the first aspect of the invention, it is preferable that the temperature of the post-heat treatment be 100° C. or lower in step α.

In the manufacturing method of the substrate with a transparent conductive film according to the first aspect of the invention, it is preferable to form the transparent conductive film on the transparent substrate by passing the transparent substrate in front of the target in step β.

In the manufacturing method of the substrate with a transparent conductive film according to the first aspect of the invention, it is preferable to use indium tin oxide (ITO) as the target in step β.

A manufacturing apparatus of a substrate with a transparent conductive film according to a second aspect of the invention is a manufacturing apparatus of a substrate with a transparent conductive film such that a transparent conductive film is disposed to be in contact with an insulating transparent substrate and includes at least a preparation chamber having an internal space into which the transparent substrate is introduced and which is set to a reduced-pressure atmosphere, a deposition chamber in which the transparent conductive film is formed on the transparent substrate, and a take-out chamber in which the transparent substrate having the transparent conductive film formed thereon is subjected to an air atmosphere, wherein a heat treatment space and a deposition space are disposed in order in a traveling direction of the transparent substrate in the deposition chamber, a temperature control unit that controls the transparent substrate to have a predetermined pre-deposition temperature is disposed in the heat treatment space, and a deposition unit that forms the transparent conductive film on the transparent substrate that has moved from the heat treatment space using a sputtering method is disposed in the deposition space.

In the manufacturing apparatus of the substrate with a transparent conductive film according to the second aspect of the invention, it is preferable that the heat treatment space and the deposition space communicate with each other in the deposition chamber, and a process gas introducer and a gas discharger be disposed such that a pressure of the heat treatment space and a pressure of the deposition space are controlled to be the same pressure.

A substrate with a transparent conductive film according to a third aspect of the invention is a substrate with a transparent conductive film such that a transparent conductive film is disposed to be in contact with an insulating transparent substrate, wherein the transparent conductive film includes: a crystal nucleus that is generated in a surface layer portion of the transparent conductive film; a crystal portion that is formed by growth from the crystal nucleus positioned in the surface layer portion and encloses the crystal nucleus; and a crystal grain boundary that is formed between crystal portions due to the crystal portions located at adjacent positions growing until colliding with each other, wherein the crystal nucleus remains in the surface layer portion in each of the crystal portions.

In the substrate with a transparent conductive film according to the third aspect of the invention, a size of the crystal nucleus is preferably 21 nm to 42 nm.

In the substrate with a transparent conductive film according to the third aspect of the invention, a size of each of the crystal portions is preferably 112 nm to 362 nm.

In the substrate with a transparent conductive film according to the third aspect of the invention, the crystal grain boundary preferably has a linear shape forming an outer shape of each of the crystal portions.

### Effects of the Invention

The manufacturing method of the substrate with a transparent conductive film according to the first aspect of the invention provides a step α of controlling a temperature of the transparent substrate to have a predetermined pre-deposition temperature so that the pre-deposition temperature of the transparent substrate is zero degree or lower. Thereafter, step α of performing a post-heat treatment on the deposited transparent conductive film is provided. Therefore, a transparent conductive film that is amorphous after deposition and has crystallinity due to post-heat treatment can be stably obtained. According to this manufacturing method, a transparent conductive film having excellent electrical characteristics (specific resistance) can be formed under a condition in which a temperature of post-heat treatment is 100° C. or lower. Therefore, the first aspect of the invention provides a manufacturing method of a substrate with a transparent conductive film in which a substrate with a transparent conductive film with low resistance can be formed using a low-temperature process. Also, the first aspect of the invention is effective as a method of forming a transparent conductive film on a substrate in which an element having low heat resistance, such as a cell in which an organic material is sealed, is disposed in advance.

Therefore, the first aspect of the invention can provide a manufacturing method of a substrate with a transparent conductive film which can sufficiently cope with even a case in which a touch panel is mounted on a display (display panel) in a smartphone application as described above (in a case in which restrictions are imposed on the temperature at the time of forming a touch sensor (temperature at the time of deposition, post-heating, or the like) due to the use of an adhesive for bonding a substrate on a color filter side (CF substrate) and a substrate on a thin film transistor (TFT) side).

The first aspect of the invention can also manufacture a substrate with a transparent conductive film that can be used for solar cell applications and various types of light receiving/emitting sensor applications in addition to such a display panel application.

The manufacturing apparatus of the substrate with a transparent conductive film according to the second aspect of the invention includes at least a preparation chamber having an internal space into which the transparent substrate is introduced and which is set to a reduced-pressure atmosphere, a deposition chamber in which the transparent conductive film is formed on the transparent substrate, and a take-out chamber in which the transparent substrate having the transparent conductive film formed thereon is subjected to an air atmosphere. In the deposition chamber, a heat treatment space and a deposition space are disposed in order in a traveling direction of the transparent substrate. Also, a temperature control unit that controls the transparent substrate to have a predetermined pre-deposition temperature is disposed in the heat treatment space, and a deposition unit that forms the transparent conductive film on the transparent substrate that has moved from the heat treatment space using a sputtering method is disposed in the deposition space.

In the manufacturing apparatus described above, two spaces, the “heat treatment space” and the “deposition space” are disposed in a single deposition chamber in a traveling direction of the transparent substrate. Therefore, the transparent substrate controlled to have a predetermined pre-deposition temperature in the heat treatment space can be promptly moved from the heat treatment space to the deposition space, and a transparent conductive film can be formed on the transparent substrate. According to this configuration, by determining the pre-deposition temperature in advance, it is possible to control the temperature after deposition of the transparent substrate (transparent conductive film) which is a temperature that has risen due to deposition. Therefore, the second aspect of the invention provides a manufacturing apparatus of a substrate with a transparent conductive film in which a substrate with a transparent conductive film with low resistance can be formed using a low-temperature process. Here, the term “temperature after deposition” means a maximum temperature (peak temperature) that the transparent substrate (transparent conductive film) reaches during deposition. For measurement of this “temperature after deposition,” Heat-label, which is available on the market, was used.

Therefore, the manufacturing apparatus according to the second embodiment of the invention contributes to the manufacture of a substrate with a transparent conductive film that can be used for solar cell applications or various types of light receiving/emitting sensor applications in addition to display panel applications.

### BRIEF DESCRIPTION OF THE DRAWINGS

FIG. 1 is a cross-sectional view showing an example of a substrate with a transparent conductive film.

FIG. 2 is a flowchart showing an example of a manufacturing method of a substrate with a transparent conductive film.

FIG. 3 is a cross-sectional view showing an example of a manufacturing apparatus of a substrate with a transparent conductive film.

FIG. 4 is a graph showing a relationship between an annealing temperature and specific resistance.

FIG. 5 is a graph showing a relationship between an H₂O (water) partial pressure and specific resistance.

FIG. 6 is a graph showing a relationship between an annealing time and specific resistance (annealing temperature: 80° C.).

FIG. 7 is a graph showing a relationship between an annealing time and specific resistance (annealing temperature: 60° C.).

FIG. 8 is a graph showing a relationship between an O₂ (oxygen) partial pressure and specific resistance.

FIG. 9 is a transmission electron microscope (TEM) image of a transparent conductive film (As depo).

FIG. 10 is an X-ray diffraction (XRD) chart of the transparent conductive film (As depo).

FIG. 11 is an XRD chart of a transparent conductive film (after annealing at 100° C.).

FIG. 12A is a TEM image of a transparent conductive film (pre-deposition temperature: 80° C.) and a scanning electron micrograph (SEM) image thereof after etching.

FIG. 12B is a TEM image of the transparent conductive film (pre-deposition temperature: 80° C.) and a SEM image thereof after etching.

FIG. 13A is a TEM image of a transparent conductive film (pre-deposition temperature: 25° C.) and a SEM image thereof after etching.

FIG. 13B is a TEM image of the transparent conductive film (pre-deposition temperature: 25° C.) and a SEM image thereof after etching.

FIG. 14A is a TEM image of a transparent conductive film (pre-deposition temperature: −16° C.) and a SEM image thereof after etching.

FIG. 14B is a TEM image of a transparent conductive film (pre-deposition temperature: −16° C.) and a SEM image thereof after etching.

FIG. 15A is a TEM image obtained after a transparent conductive film (pre-deposition temperature: 80° C.) is subjected to an annealing treatment at 100° C.

FIG. 15B is a TEM image obtained after a transparent conductive film (pre-deposition temperature: −16° C.) is subjected to an annealing treatment at 100° C.

FIG. 16 shows TEM images of a transparent conductive film (pre-deposition temperature: −16° C.), and shows enlarged views for explaining a process of growth of crystals due to crystal nuclei positioned in the surface layer portion of the transparent conductive film.

FIG. 17A is a view for explaining crystal growth of a transparent conductive film (pre-deposition temperature: 80° C.).

FIG. 17B is a view for explaining crystal growth of a transparent conductive film (pre-deposition temperature: −16° C.).

FIG. 18 is a TEM image of a transparent conductive film (pre-deposition temperature: −16° C.).

FIG. 19 is a view obtained by image processing the TEM image shown in FIG. 18 and a view showing crystal nuclei remaining in the transparent conductive film.

FIG. 20 is a view corresponding to outer contours of the crystal portions created on the basis of the TEM image shown in FIG. 18.

### DETAILED DESCRIPTION OF THE INVENTION

Hereinafter, preferred embodiments of a manufacturing method and a manufacturing apparatus of a substrate with a transparent conductive film according to the invention will be described on the basis of the drawings. Further, the embodiments will be described in detail for better understanding of the spirit of the invention and do not limit the invention unless otherwise specified.

### First Embodiment

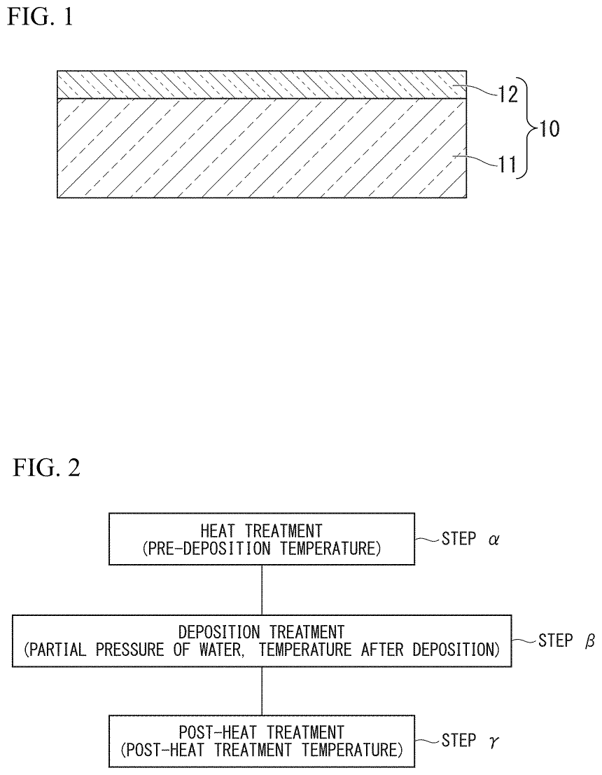

Hereinafter, a manufacturing method and a manufacturing apparatus of a substrate with a transparent conductive film such that a transparent conductive film is disposed to be in contact with an insulating transparent substrate will be described with reference to FIGS. 1 to 3.

FIG. 1 is a cross-sectional view showing an example of a substrate with a transparent conductive film. In FIG. 1, reference numeral 10 denotes a substrate with a transparent conductive film, reference numeral 11 denotes an insulating transparent substrate, and reference numeral 12 denotes a transparent conductive film.

The substrate with a transparent conductive film having the above-described configuration is manufactured by a manufacturing method shown in a flowchart of FIG. 2. That is, a manufacturing method of a substrate with a transparent conductive film according to the embodiment of the invention is a manufacturing method of a substrate with a transparent conductive film such that a transparent conductive film 12 is disposed to be in contact with an insulating transparent substrate 11 and includes, in order, at least a step α (a first step) of controlling the transparent substrate to have a predetermined pre-deposition temperature in a heat treatment space with a desired reduced-pressure atmosphere, a step β (a second step) of applying a sputtering voltage to a target forming a base material of the transparent conductive film to perform sputtering to deposit the transparent conductive film on the transparent substrate having the predetermined temperature in a deposition space with a desired process gas atmosphere, and a step α (a third step) of performing a post-heat treatment on the transparent conductive film formed on the transparent substrate in an air atmosphere in which the pre-deposition temperature in step α is zero degree or lower.

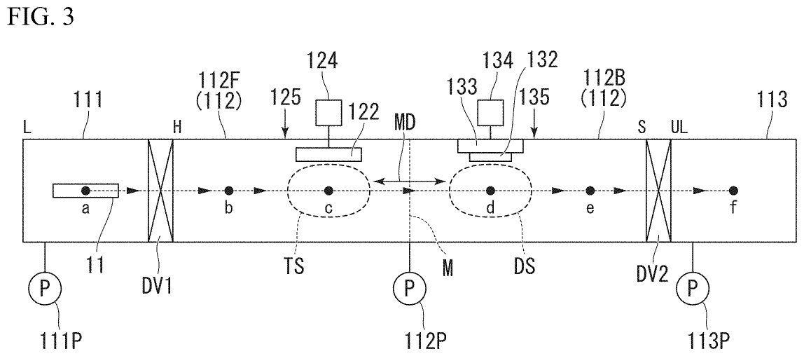

In the above-described manufacturing method, the step α and step β are performed by using, for example, a sputtering apparatus (manufacturing apparatus of a substrate with a transparent conductive film) as shown in FIG. 3. In the sputtering apparatus, the transparent substrate is horizontally transferred, and the transparent conductive film is formed using a sputtering method such that an upper surface of the transparent substrate is a surface to be deposited (sputter-down type).

A manufacturing apparatus of a substrate with a transparent conductive film in FIG. 3 includes at least a preparation chamber 111 having an internal space into which the transparent substrate 11 is introduced and which is set to a reduced-pressure atmosphere, a deposition chamber 112 in which the transparent conductive film 12 is formed on the transparent substrate 11, and a take-out chamber 113 in which the transparent substrate 11 having the transparent conductive film 12 formed thereon is subjected to an air atmosphere. A gas discharger P (111P, 112P, and 113P) is provided in each of the preparation chamber 111, the deposition chamber 112, and the take-out chamber 113 to set an internal space thereof to a reduced-pressure atmosphere. Particularly, the gas discharger 112P of the deposition chamber 112 is disposed at an intermediate position M between a heat treatment space TS and a deposition space DS to be described below. Therefore, mutual influence of the heat treatment space TS and the deposition space DS can be avoided.

A distance MD between the heat treatment space TS and the deposition space DS is appropriately determined in consideration of a pre-deposition temperature or a temperature after deposition of a substrate, a transfer speed of the substrate, and deposition conditions (pressure, sputtering power, and the like). In the deposition chamber 112, a process gas introducer 125 used for the heat treatment space TS and a process gas introducer 135 used for the deposition space DS are respectively provided.

A door valve DV1 is disposed between the preparation chamber 111 and the deposition chamber 112, and a door valve DV2 is disposed between the deposition chamber 112 and the take-out chamber 113 to be openable and closeable, respectively.

When the door valve DV1 is set to an open state, the internal space of the preparation chamber 111 and the internal space of the deposition chamber 112 communicate with each other, and the transparent substrate 11 can be transferred (from the portion shown by reference letter a to the portion shown by reference letter b). Similarly, when the door valve DV2 is set to an open state, the internal space of the deposition chamber 112 and the internal space of the take-out chamber 113 communicate with each other, and the transparent substrate 11 can be transferred (from the portion shown by reference letter e to the portion shown by reference letter f).

When the door valve DV1 and the door valve DV2 are set to a closed state at the same time, the internal space of the deposition chamber 112 becomes a single sealed space.

Inside the deposition chamber 112, a heat treatment space TS and a deposition space DS are disposed in order in a traveling direction of the transparent substrate 11 (in a direction of dotted arrows traversing reference letters b, c, d, and e in this order).

In the heat treatment space TS, a temperature control unit (hereinafter also referred to as a temperature regulating device) including 122 and 124 that control the transparent substrate 11 to have a predetermined pre-deposition temperature is disposed. In the deposition space DS, a deposition unit including 132, 133, and 134 that form the transparent conductive film 12 on the transparent substrate 11 that has moved from the heat treatment space TS using a sputtering method is disposed.

Here, reference numeral 122 is a heater or a cooler, and reference numeral 124 is a power supply of the heater or the cooler. Reference numeral 132 is a target used for a transparent conductive film, reference numeral 133 is a backing plate on which the target is placed, and reference numeral 134 is a power supply that supplies direct current (DC) power to the backing plate.

Step α and step β are performed under various conditions described below using the sputtering apparatus (the manufacturing apparatus of a substrate with a transparent conductive film) shown in FIG. 3 having the configuration described above.

### (Step α)

Insulating transparent substrate: A transparent substrate made of glass (1100 mm×1400 mm in size, 3.0 mm in thickness) was used. The substrate transfer was in an 1100 mm direction.

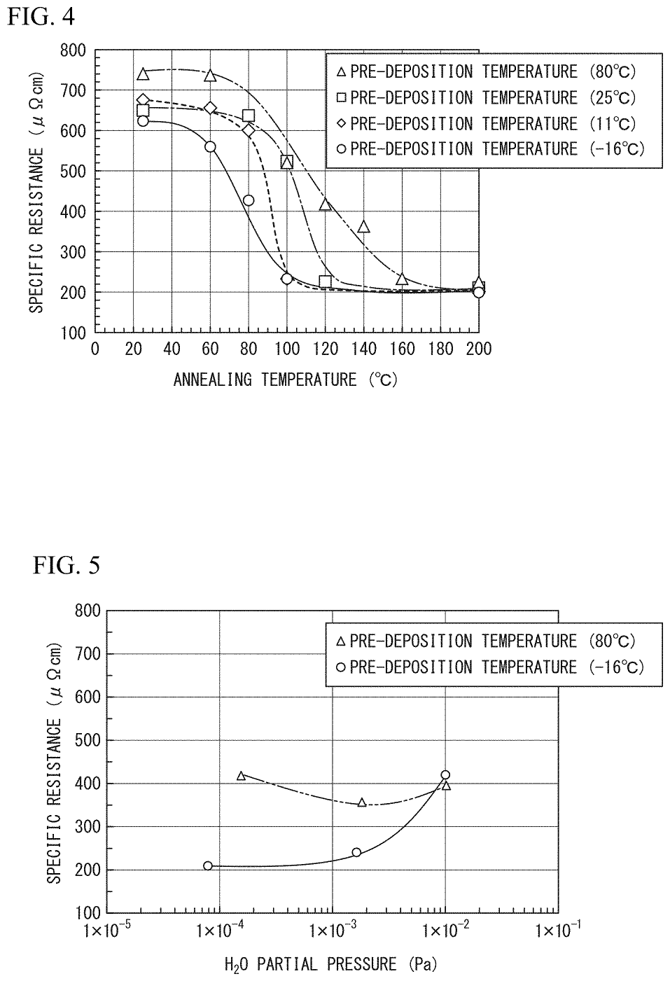

Heat treatment condition: In a case of heated deposition or room-temperature deposition, a substrate was heat treated by the temperature regulating device so that the substrate had a predetermined temperature (pre-deposition temperature: 25° C. or 80° C. in FIG. 4 to be described below) after the substrate had passed (transferred) in front of the temperature regulating device. In a case of cooled deposition, a substrate was heat treated by the temperature regulating device so that the substrate had a predetermined temperature (pre-deposition temperature: −16° C. or 11° C. in FIG. 4 to be described below) in a state in which the substrate was stationary in front of the temperature regulating device.

Here, when the pre-deposition temperatures have been set to “−16°, 11° C., 25° C., and 80° C.,” temperatures after deposition respectively correspond to “a temperature lower than 29° C., a temperature lower than 29° C., 46° C. or higher and lower than 49° C., and 110° C. or higher and lower than 116° C.” in order.

Heat treatment atmosphere: A process gas used was a mixed gas of Ar, O₂, and H₂O, and a pressure was set to 0.4 Pa.

### (Step β)

Deposition method: Indium tin oxide (ITO) film was formed by in-line deposition using direct-current (DC) sputtering method.

Deposition atmosphere: A process gas used was a mixed gas of Ar, O₂, and H₂O, and a pressure was set to 0.4 Pa. The flow rates of the respective gases were Ar (180 sccm), O₂ (1 to 8 sccm), and H₂O (2 to 50 sccm).

Substrate transfer speed: 1960 mm/min

Power density applied to the target: 6.0 W/cm²

Target composition: Tin-doped indium oxide (ITO) in which indium oxide was doped with tin oxide at 10% by mass [In₂O₃ doped with SnO₂ at 10% by mass].

Hereinafter, step α and step β shown in FIG. 2 will be described in detail.

First, the transparent substrate 11 (hereinafter also referred to as a substrate) made of glass is transferred from the preparation chamber 111 (position shown by reference letter a) to the deposition chamber 112 (position shown by reference letter b) using a transfer device (not shown). The transparent substrate 11 is caused to pass through an inside of a space (position shown by reference letter c) in front of the temperature regulating device 122 (heat treatment space TS) in a state in which a desired temperature is maintained in a process gas atmosphere formed of a mixed gas of Ar, O₂, and H₂O, or to be stationary in the inside of the space (position shown by reference letter c) in front of the temperature regulating device 122 (heat treatment space TS). Therefore, the transparent substrate 11 is brought to a predetermined pre-deposition temperature.

A process gas (sputtering gas) formed of a mixed gas of Ar, O₂, and H₂O is introduced into the deposition space DS, and a sputtering voltage, for example, a direct current (DC) voltage is applied as a sputtering voltage to a target 132 through a backing plate 133 by the power supply 134. Ions of the sputtering gas such as Ar excited by plasma generated due to the application of the sputtering voltage cause atoms constituting tin-doped indium oxide (ITO) to eject out of the target 132. The transparent substrate 11 having been subjected to the above-described heat treatment is moved to pass through the inside of the space in front of the target 132 (deposition space DS) in a state described above. That is, transparent substrate 11 passes through a position shown by reference letter d from the position shown by reference letter c and is moved to a position of the reference letter e. Therefore, the transparent conductive film 12 is formed on the transparent substrate 11. Thereafter, when the transparent substrate 11 on which the transparent conductive film 12 is formed is moved to a position shown by reference letter f and the take-out chamber 113 is open to the atmosphere, a first sample (As depo) obtained by deposition (deposition) is obtained. In the following description, a film or sample obtained by deposition (deposition) will be referred to as “As depo” in some cases.

### (Step γ)

Next, step γ of performing a post-heat treatment on the transparent conductive film (first sample of As depo) formed on the transparent substrate is performed in an air atmosphere. The transparent conductive film in the first sample of As depo is amorphous and hardly has any crystallinity. In contrast, when the transparent conductive film is subjected to the post-heat treatment, the transparent conductive film is crystallized. Due to this crystallization, the transparent conductive film can have electrical characteristics of low resistance.

Conventionally, crystallization was obtained only after performing a post-heat treatment at a high temperature of approximately 200° C., and thereby resistance of a transparent conductive film could be reduced. In contrast, crystallization can be achieved even when a post-heat treatment is performed at a low temperature of 100° C. or lower in the embodiment of the invention. Therefore, according to the manufacturing method according to the embodiment of the invention, a device, in which a low-resistance transparent conductive film is provided even on a thin film transistor (TFT) substrate which cannot withstand high-temperature heating, can be constructed.

### (Experimental Example 1: Relationship Between Annealing Temperature (Temperature of Post-Heat Treatment) and Specific Resistance)

FIG. 4 is a graph showing a relationship between an annealing temperature and specific resistance and is a result of investigation on four conditions of pre-deposition temperatures (80° C., 25° C., 11° C., and −16° C.). A symbol Δ indicates an observation result at 80° C., a symbol □ indicates an observation result at 25° C., a symbol ⋄ indicates an observation result at 11° C., and a symbol ◯ indicates an observation result at −16° C. At that time, an annealing time was fixed (1 hour).

From FIG. 4, the following points became clear.

(A1) When the annealing temperature (temperature of post-heat treatment) was increased, specific resistance of the first sample (As depo sample) formed under any pre-deposition temperature can be reduced (Specific resistance [μΩcm] can be changed from approximately 700 to approximately 200).

(A2) Reduction of the resistance in (A1) described above is dependent on pre-deposition temperature. The higher the pre-deposition temperature is, the higher the annealing temperature (temperature of post-heat treatment) is required to reduce resistance.

(A3) As the pre-deposition temperature is lowered, the annealing temperature (temperature of post-heat treatment) for reducing resistance becomes even lower. Of these, in a case in which the pre-deposition temperature is zero degree or lower (symbol ◯), a transparent conductive film having specific resistance [μΩcm] of approximately 240 can be obtained even when the annealing temperature (temperature of post-heat treatment) is 100° C. or lower.

Therefore, it was confirmed from FIG. 4 that the annealing temperature (temperature of post-heat treatment) for reducing resistance decreases as the pre-deposition temperature decreases.

### (Experimental Example 2: Relationship Between H₂O (Water) Partial Pressure and Specific Resistance)

FIG. 5 is a graph showing a relationship between an H₂O (water) partial pressure and specific resistance and is a result of investigation on two conditions of pre-deposition temperatures (80° C. and −16° C.). A symbol Δ indicates an observation result at 80° C., and a symbol ◯ indicates an observation result at −16° C. In the present experimental example, the H₂O (water) partial pressure during deposition was changed within a range of 8×10⁻⁵ to 1×10⁻² [Pa]. At that time, an annealing temperature (temperature of post-heat treatment) was 120° C.

From FIG. 5, the following points became clear.

(B1) When the pre-deposition temperature was 80° C., it was observed that specific resistance tends to be a local minimum value (approximately 360 [μΩcm]) when the H₂O (water) partial pressure was approximately 2×10⁻³ [Pa].

(B2) When the pre-deposition temperature was −16° C., a tendency that specific resistance also decreased according to decrease in the H₂O (water) partial pressure was observed. It was found that the specific resistance (approximately 210 [μΩcm]) when the H₂O (water) partial pressure was approximately 8×10⁻⁵ [Pa] was halved compared to the specific resistance (approximately 410 [μΩcm]) when the H₂O (water) partial pressure was approximately 1×10⁻² [Pa].

Therefore, it was confirmed from FIG. 5 that a process margin of the H₂O (water) partial pressure with respect to the specific resistance increased due to the annealing treatment (post-heat treatment) when the pre-deposition temperature was lowered.

### (Experimental Example 3: Relationship Between Annealing Time (Time of Post-Heat Treatment) and Specific Resistance (PART 1))

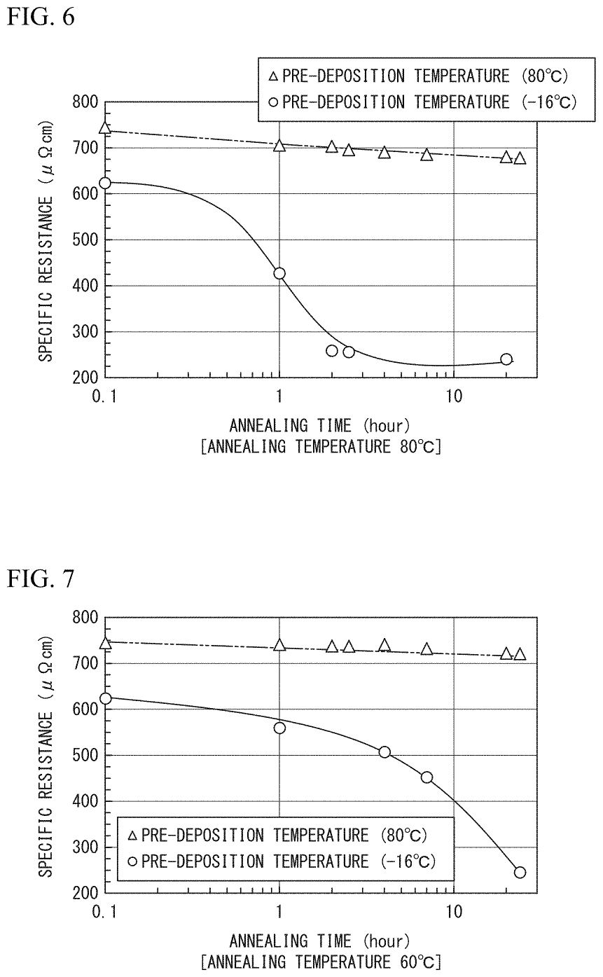

FIG. 6 is a graph showing a relationship between an annealing time and specific resistance and is a result of investigation on two conditions of pre-deposition temperatures (80° C. and −16° C.). A symbol Δ indicates an observation result at 80° C., and a symbol ◯ indicates an observation result at −16° C. At that time, the annealing temperature (temperature of post-heat treatment) was 80° C.

In the present experimental example, the annealing time was changed within a range of 1 to 24 hours. The numerical value of specific resistance plotted at 0.1 hours on a horizontal axis for convenience is a result without annealing treatment (result after deposition).

From FIG. 6, the following points became clear.

(C1) When the pre-deposition temperature is 80° C., specific resistance hardly changes even after the annealing treatment is performed for 24 hours (after deposition: approximately 740 [μΩcm], after 24 hours: approximately 670 [μΩkm]).

(C2) When the pre-deposition temperature is −16° C., the specific resistance shows a tendency to sharply decrease when the annealing treatment is performed for 1 hour, and the specific resistance becomes approximately one third when the annealing treatment is performed for 24 hours (after deposition: approximately 620 [μΩcm], after 1 hour: from approximately 420 [μΩcm], after 2 hours: approximately 250 [μΩcm], and after 20 hours: approximately 239 [μΩcm]).

Therefore, it was confirmed from FIG. 6 that, when the pre-deposition temperature was lowered, specific resistance could be reduced depending on the annealing treatment time even with a low temperature annealing treatment (post-heat treatment) at 80° C.

### (Experimental Example 4: Relationship Between Annealing Time (Time of Post-Heat Treatment) and Specific Resistance (PART 2))

FIG. 7 is a graph showing a relationship between an annealing time and specific resistance, and is a result of investigation on two conditions of pre-deposition temperatures (80° C. and −16° C.). A symbol Δ indicates an observation result at 80° C., and a symbol ◯ indicates an observation result at −16° C. At that time, the annealing temperature (temperature of post-heat treatment) was 60° C.

In the present experimental example, the annealing time was changed within a range of 1 to 24 hours. The numerical value of specific resistance plotted at 0.1 hour on a horizontal axis for convenience is a result without annealing treatment (result after deposition).

From FIG. 7, the following points became clear.

(D1) When the pre-deposition temperature is 80° C., specific resistance hardly changes even after the annealing treatment was performed for 24 hours (after deposition: approximately 740 [μΩcm], after 24 hours: approximately 725 [μΩcm]).

(D2) When the pre-deposition temperature is −16° C., the specific resistance shows a tendency to moderately decrease when the annealing treatment is performed for 1 hour, and the specific resistance becomes approximately one third when the annealing treatment is performed for 24 hours (after deposition: approximately 620 [μΩcm], after 1 hour: approximately 560 [μΩcm], after 4 hours: approximately 500 [μΩcm], after 7 hours: approximately 450 [μΩcm], after 24 hours: approximately 244 [μΩcm]).

Therefore, it was confirmed from FIG. 7 that, when the pre-deposition temperature was lowered, the specific resistance could be reduced depending on the annealing treatment time even with a low temperature annealing treatment (post-heat treatment) at 60° C.

In the result shown in FIG. 7 [low-temperature annealing treatment (post-heat treatment) at 60° C.] of the present experimental example, reduction in specific resistance requires a time compared to the result shown in FIG. 6 [low-temperature annealing treatment (post-heat treatment) at 80° C.] described above. On the other hand, when the annealing treatment was performed for approximately 24 hours, it became clear that specific resistance could be sufficiently reduced by performing the annealing treatment even in the low temperature region of 80° C. and 60° C. (specific resistance after 20 hours at 80° C. was 239 [μΩcm] and specific resistance after 24 hours at 60° C. was 244 [μΩcm]).

### (Experimental Example 5: Relationship Between O₂ (Oxygen) Partial Pressure and Specific Resistance)

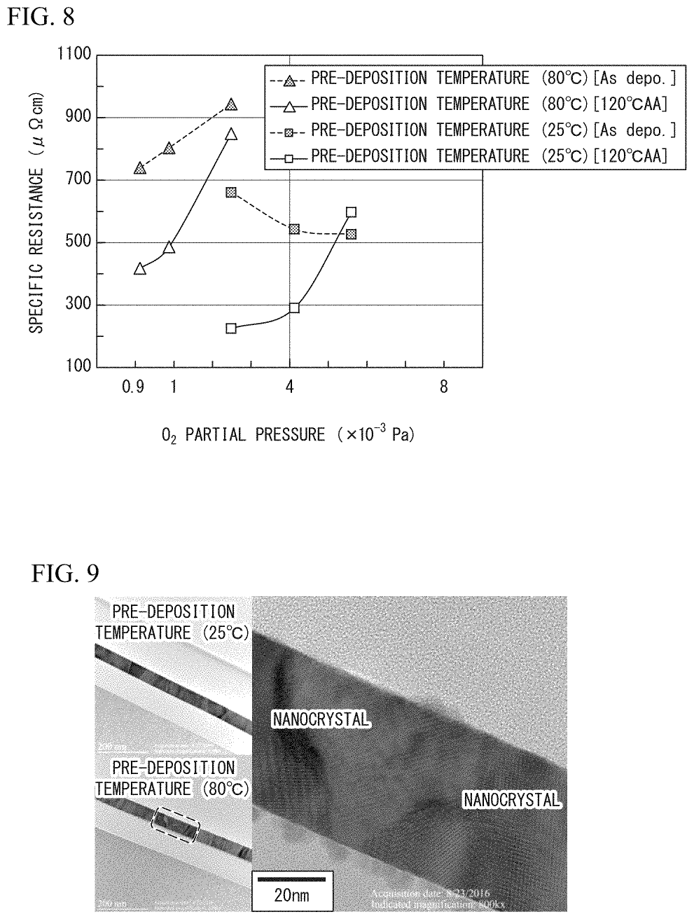

FIG. 8 is a graph showing a relationship between an O₂ (oxygen) partial pressure and specific resistance, and is a result of investigation on two conditions of pre-deposition temperatures (80° C. and 25° C.). A symbol ▴ indicates an observation result at 80° C. (after deposition (As depo), a symbol Δ indicates an observation result at 80° C. (after annealing treatment), a symbol ▪ indicates an observation result at 25° C. (after deposition (As depo), and a symbol □ indicates an observation result at 25° C. (after annealing treatment). At that time, the annealing temperature (temperature of post-heat treatment) was 120° C.

From FIG. 8, the following points became clear.

(E1) When the O₂ (oxygen) partial pressure is controlled to be lowered, specific resistance after the annealing treatment can be reduced. The effect becomes larger as the pre-deposition temperature becomes lower.

(E2) When the O₂ (oxygen) partial pressure is controlled to be lowered, the effect of reducing the specific resistance after the annealing treatment occurs in a region in which the O₂ (oxygen) partial pressure is higher as the pre-deposition temperature becomes lower.

Therefore, it was confirmed from FIG. 8 that, when slight heating was applied (when the condition of the pre-deposition temperature was set to 80° C. as compared with that of 25° C.), a tendency of deterioration in specific resistance, that is, the effect due to the annealing treatment tended to decrease.

FIG. 9 is a transmission electron microscope (TEM) image of the transparent conductive film (As depo). An image on an upper left side shows a case in which the pre-deposition temperature is 25° C. and an image on a lower left shows a case in which the pre-deposition temperature is 80° C. A large image on the right side is an enlarged image of the area surrounded by a dotted line in the image on the lower left side.

From FIG. 9, the following points became clear.

(F1) When the pre-deposition temperature is 80° C., nanocrystals are present in a transparent conductive film.

(F2) A proportion of the nanocrystals increases as the pre-deposition temperature increases (comparison between 25° C. and 80° C.).

Therefore, it was presumed that a main cause of the above-described result shown in FIG. 8 was due to generation of nanocrystals inside the transparent conductive film. Therefore, it was determined that a process capable of limiting nanocrystallization was required to be developed.

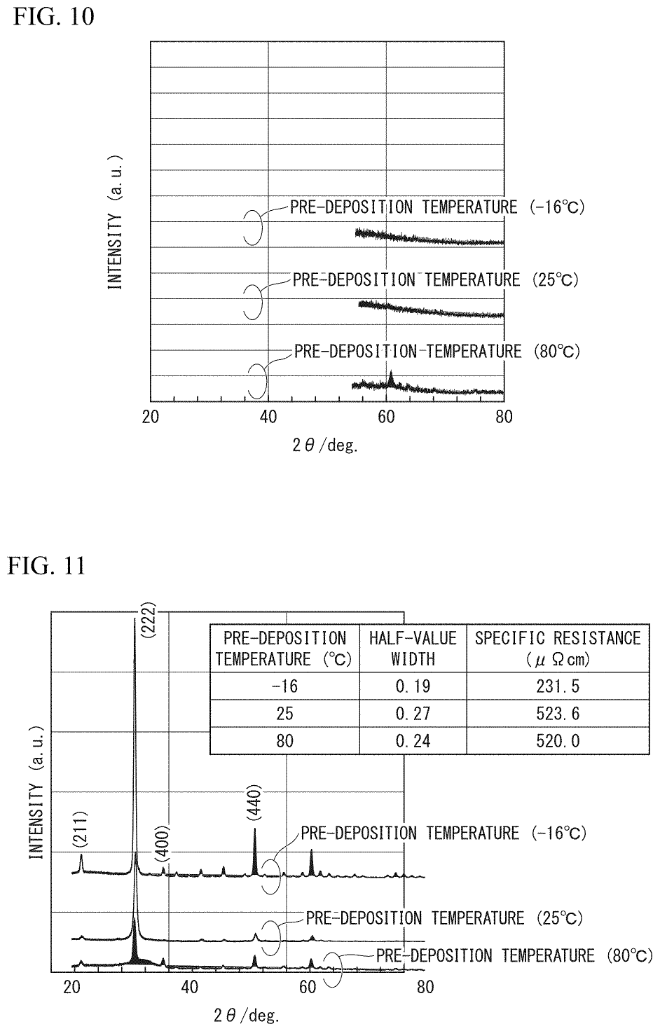

FIG. 10 is an X-ray diffraction (XRD) chart of a transparent conductive film (As depo), and FIG. 11 is an XRD chart of a transparent conductive film (after annealing at 100° C.). These are results of investigation on three conditions of pre-deposition temperatures (80° C., 25° C., and −16° C.).

From FIGS. 10 and 11, the following points became clear.

(G1) A film quality of the transparent conductive film at a step after deposition (As depo) significantly differs depending on the pre-deposition temperature. When the pre-deposition temperature was 80° C., presence of crystallinity was confirmed from observation of the diffraction peak attributable to (222). When the pre-deposition temperature was 25° C., a slight crystallinity was confirmed. When the pre-deposition temperature was −16° C., it was amorphous.

(G2) The transparent conductive film at a step after annealing at 100° C. did not depend on the pre-deposition temperature and showed crystallinity. However, it was found that crystalline qualities were significantly different, and a transparent conductive film with higher crystallinity was formed as the pre-deposition temperature becomes lower.

(G3) Particularly, the transparent conductive film in a case in which the pre-deposition temperature was set to zero degree or lower (−16° C.), a half-value width of the diffraction peak of (222) was 0.19 when the transparent conductive film was subjected to an annealing treatment. From this, it was found that a transparent conductive film with high crystallinity could be obtained when low temperature annealing at 100° C. or lower was performed after the transparent conductive film was formed with a pre-deposition temperature set to zero degree or lower.

Therefore, it was confirmed from the XRD charts in FIGS. 10 and 11 that, when an amorphous transparent conductive film with excellent quality was formed at a step after deposition (As depo) and an annealing treatment was performed thereon, the transparent conductive film exhibited high crystallinity.

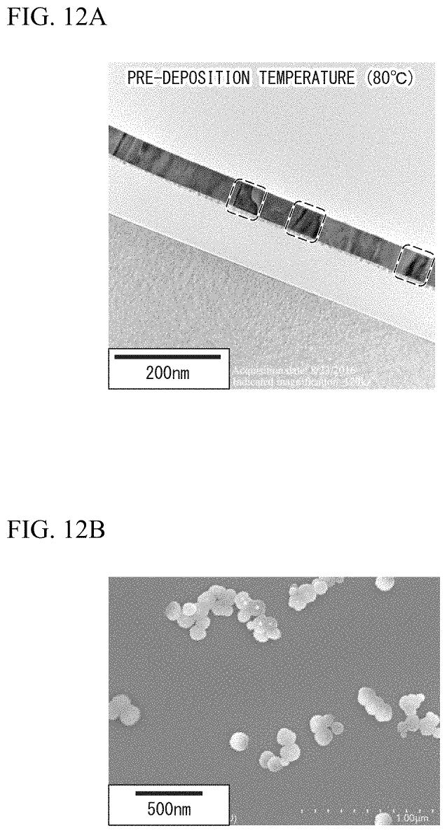

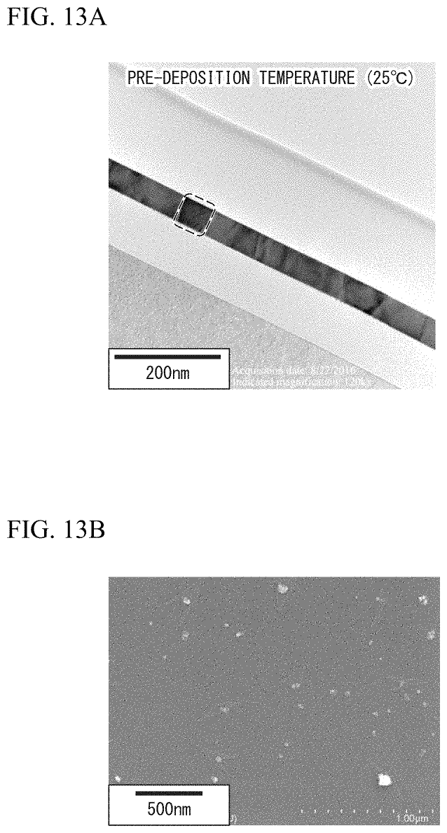

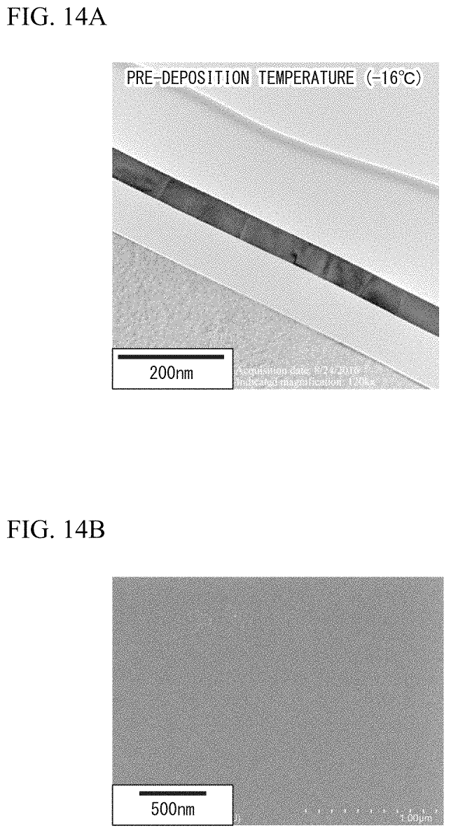

FIGS. 12A, 13A, and 14A show TEM images of a transparent conductive film. FIGS. 12B, 13B and 14B show scanning electron micrograph (SEM) images after etching. FIGS. 12A and 12B show a case in which a pre-deposition temperature is 80° C., FIGS. 13A and 13B show a case in which the pre-deposition temperature is 25° C., and FIGS. 14A and 14B show a case in which the pre-deposition temperature is −16° C.

From FIG. 12A to FIG. 14B, the following points became clear.

(H1) In the TEM images shown in FIGS. 12A and 13A, a portion surrounded by a dotted line is a portion in which nanocrystals are confirmed. When the TEM images were compared with each other, it was found that there were less nanocrystals present in a transparent conductive film in which the pre-deposition temperature was relatively lower (FIGS. 13A and 13B) than those present in a transparent conductive film in which the pre-deposition temperature was higher (FIGS. 12A and 12B).

(H2) In the SEM image after etching (FIGS. 12B and 13B), portions that look granular are residues (ITO particle having crystallinity) reflecting nanocrystals present in the transparent conductive films. From this, it was found that as the pre-deposition temperature decreased, the residues became finer and the number of residues also drastically decreased.

Accordingly, from the TEM images and the SEM images after etching shown in FIGS. 12A to 13B, it was confirmed that the number of nanocrystals generating in the transparent conductive film gradually decreased as the pre-deposition temperature became lower. Particularly, as shown in FIGS. 14A and 14B, it was confirmed that generation of the nanocrystals present in the transparent conductive film were suppressed when the pre-deposition temperature was set to zero degree or lower.

In the embodiment of the invention, as a method of regulating a temperature so that a temperature of the transparent substrate having the transparent conductive film formed thereon after deposition is lower than 29° C., for example, it is preferable to place the transparent substrate on a metallic flat plate-like tray having excellent conductivity so that a non-deposition side of the transparent substrate comes into contact therewith and perform the above-described step α and step β. According to this configuration, the temperature can be regulated so that the temperature of the transparent substrate having the transparent conductive film formed thereon after deposition is lower than 29° C. due to a sufficient thermal capacity of the tray and thermal resistance of both members (the insulating transparent substrate and the tray having excellent conductivity). As long as such thermal design can be performed, the invention is not limited to the above-described method, and other methods may be employed.

### Second Embodiment

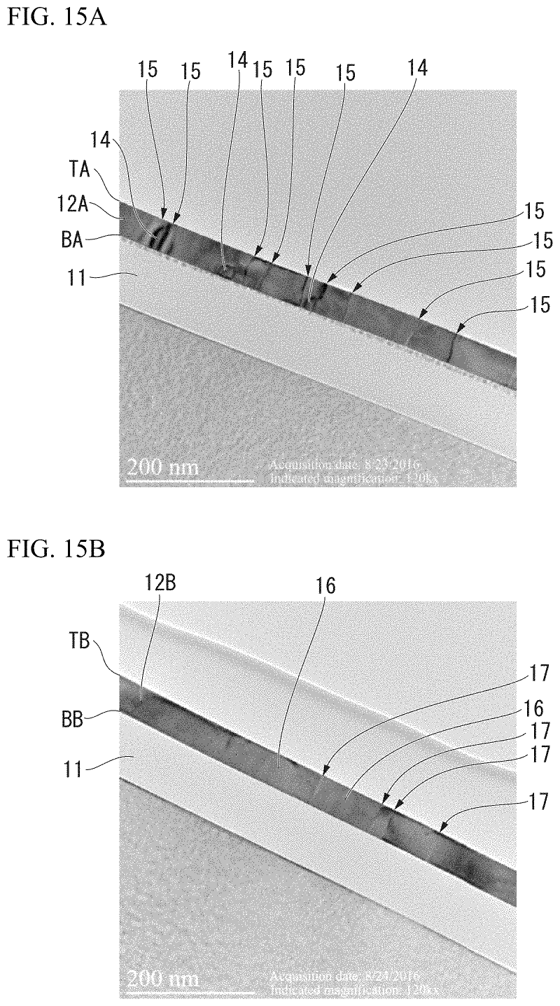

Next, an embodiment of the transparent conductive film shown in FIGS. 14A and 14B, that is, the substrate with a transparent conductive film in which a pre-deposition temperature is −16° C. will be described with reference to FIGS. 15A to 17B.

In FIGS. 15A to 17B, members the same as those in the first embodiment will be denoted by the same reference numerals and description thereof will be omitted or simplified.

FIG. 15A is a TEM image obtained after a transparent conductive film 12A (pre-deposition temperature: 80° C.) is subjected to an annealing treatment at 100° C. on a transparent substrate 11. FIG. 15B is a TEM image obtained after a transparent conductive film 12B (pre-deposition temperature: −16° C.) is subjected to an annealing treatment at 100° C. on the transparent substrate 11.

In FIG. 15A, a lower portion of the transparent conductive film 12A is positioned on a substrate side, that is, at an interface BA between the transparent conductive film 12A and the transparent substrate 11. On the other hand, an upper portion of the transparent conductive film 12A is positioned on a side opposite to the interface BA between the transparent conductive film 12A and the transparent substrate 11, that is, on a surface layer TA (a surface layer side, or a surface layer portion) of the transparent conductive film 12A.

In FIG. 15B, a lower portion of the transparent conductive film 12B is positioned on a substrate side, that is, at an interface BB between the transparent conductive film 12B and the transparent substrate 11. On the other hand, an upper portion of the transparent conductive film 12B is positioned on a side opposite to the interface BB between the transparent conductive film 12B and the transparent substrate 11, that is, on a surface layer TB (a surface layer side, or a surface layer portion) of the transparent conductive film 12B.

As shown in FIG. 15A, it was confirmed that a plurality of nanocrystals 14 were formed at the interface BA between the transparent substrate 11 and the transparent conductive film 12A in the transparent conductive film 12A in which the pre-deposition temperature was 80° C. In addition, it was confirmed that crystal grain boundaries 15 were formed around the nanocrystals 14. It was confirmed that the size of each of the nanocrystals was approximately 50 nm to 100 nm and specific resistance was 520 μΩcm.

On the other hand, as shown in FIG. 15B, the nanocrystals 14 as in FIG. 15A were not observed in the transparent conductive film 12B in which the pre-deposition temperature was −16° C., and large crystals 16 of approximately 100 nm to 200 nm in size (crystal portion 21 to be described below) were observed. Also, it was confirmed that crystal grain boundaries 17 fewer in number than those in FIG. 15A were formed. Further, it was confirmed that specific resistance was 220 μΩcm. As will be described below, each of the crystal grain boundaries 17 is formed between the crystal portions 21 grown from crystal nuclei 20 at adjacent positions.

It is ascertained from results shown in FIGS. 15A and 15B that the number of crystal grain boundaries was small and crystals with large domain were formed in the transparent conductive film in which the pre-deposition temperature was −16° C. compared to a case in which the pre-deposition temperature was 80° C.

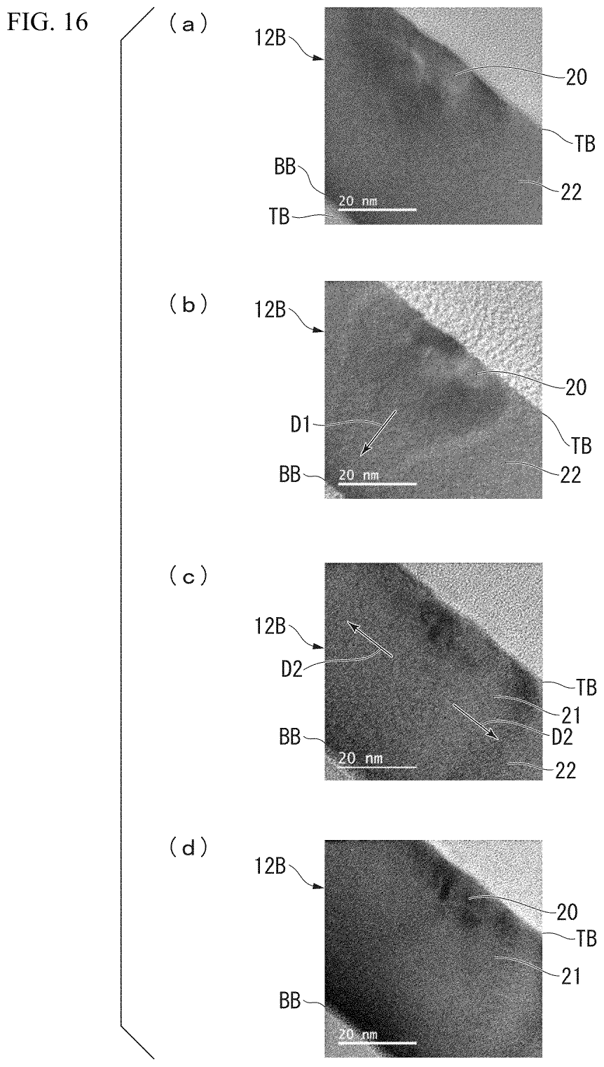

Next, a process of crystal growth in the transparent conductive film (pre-deposition temperature: −16° C.) shown in FIG. 15B will be described with reference to FIG. 16. FIGS. 16(a) to 16(d) are TEM images showing a process in which domain crystals are formed.

First, as shown in FIG. 16(a), it was confirmed that, in the transparent conductive film 12B in which the pre-deposition temperature was −16° C., the crystal nucleus 20 was formed on the surface layer TB (film surface side) of the transparent conductive film 12B. The crystal nucleus 20 is a starting point for crystal growth, and can be referred to as a nuclide, nucleus, seed, or seed crystal. Also, it was confirmed that a size of the crystal nucleus 20 was approximately 21 nm to 42 nm. Further, a region other than the crystal nucleus 20, that is, a region indicated by reference numeral 22 is an amorphous portion.

Next, as the crystal growth proceeds from the crystal nucleus 20, the crystals grows toward a thickness direction (reference numeral D1) of the transparent conductive film 12B with the crystal nucleus 20 as a starting point as shown in FIG. 16(b). As the crystal growth further proceeds, as shown in FIG. 16(c), the crystal grows in a lateral direction of the transparent conductive film 12B (reference numeral D2, a direction parallel to a plane of the substrate). As a result, the crystal portion 21 that encloses the crystal nucleus 20 is formed in the transparent conductive film 12B. The crystal portion 21 is a portion grown from the crystal nucleus 20 positioned in the surface layer TB.

Finally, it is ascertained that a large crystal portion 21 is formed as shown in FIG. 16 (d). It is ascertained from the results shown in FIGS. 16(a) to 16(d) that, in the transparent conductive film 12B obtained by low temperature deposition, the crystal growth proceeds with the crystal nucleus 20 formed in an outermost surface of the crystal, that is, the surface layer TB (surface layer portion) as a starting point, and the large crystal portion 21 is formed. Further, it is ascertained that the crystal nucleus 20 remains even after the crystal portion 21 has been formed as shown in FIG. 16 (d).

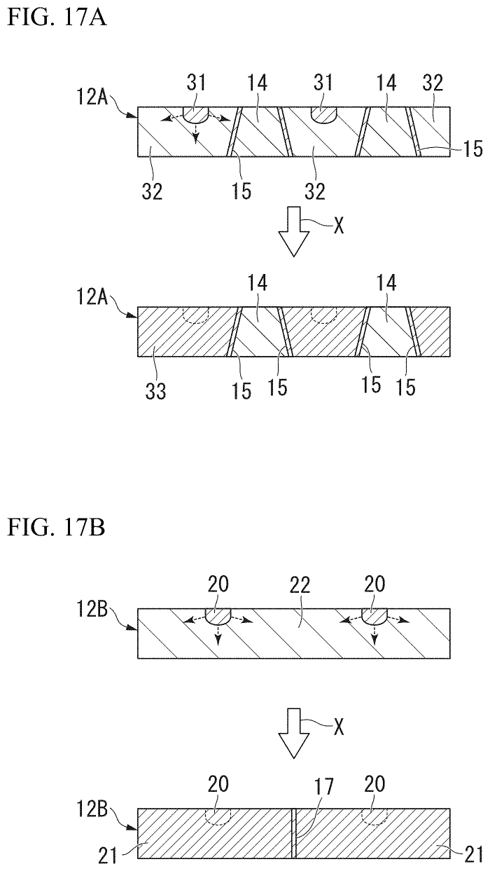

Next, a difference in crystal growth (mechanism of crystal growth) between the transparent conductive film 12A (pre-deposition temperature: 80° C.) and the transparent conductive film 12B (pre-deposition temperature: −16° C.) will be described with reference to FIGS. 17A and 17B.

FIG. 17A is a view for describing crystal growth in a case in which nanocrystals are present in the transparent conductive film 12A in which the pre-deposition temperature is 80° C. FIG. 17B is a view for describing crystal growth in a case in which nanocrystals are not present in a transparent conductive film 12 in which the pre-deposition temperature is −16° C.

Hereinafter, the reason why reduction in resistance can be realized in the transparent conductive film 12B (ITO film, As depo) deposited at a low temperature and the reason why the reduction in resistance cannot be easily realized in the transparent conductive film 12A deposited by a conventional deposition method (deposition at a medium-high temperature) will be described by comparing FIG. 17A with FIG. 17B.

FIG. 17A shows a condition in which reduction in resistance cannot be easily realized by low temperature annealing.

In FIG. 17A, reference numeral 30 denotes a crystal nucleus, reference numeral 32 denotes an amorphous portion, reference numeral 14 denotes a nanocrystal, reference numeral 15 denotes a crystal grain boundary (interface) between the amorphous portion 32 and the nanocrystal 14, and reference numeral 33 denotes a crystal portion.

In the transparent conductive film 12A formed by a medium-high temperature deposition (deposition under a condition that the pre-deposition temperature described above is 80° C.), it is considered that the crystal nuclei 31 is present in addition to the nanocrystal 14 observed by TEM images. Also, under such a condition of medium-high temperature deposition, the nanocrystal 14 and the crystal grain boundary 15 are formed due to deposition.

Thereafter, when an annealing treatment (reference letter X) is performed, crystal growth proceeds with the crystal nucleus 31 as a starting point and the crystal portion 33 is formed. However, the crystal growth is limited by the nanocrystal 14 during crystal growth. For this reason, the transparent conductive film 12A having a large number of crystal grain boundaries 15 is formed, and thus reduction in resistance cannot be easily realized.

In contrast, as shown in FIG. 17B, in the transparent conductive film 12 formed by deposition using a low-temperature sputtering method (deposition under a condition that the pre-deposition temperature described above is −16° C.), observation from the TEM image reveals that the crystal nucleus 20 and an amorphous portion 22 are present. Further, when deposition is performed by a low-temperature sputtering method, the nanocrystal 14 and the large number of crystal grain boundaries 15 are not present in the transparent conductive film 12B.

Thereafter, by performing an annealing treatment (reference letter X), crystal growth proceeds with the crystal nucleus 20 positioned in the surface layer TB as a starting point. Since there are no factors that inhibit crystal growth as in the medium-high temperature deposition in FIG. 17A (the nanocrystal 14, the large number of crystal grain boundaries 15), crystal growth proceeds until the crystal portions 21 grown from the adjacent crystal nuclei 20 collide with each other. Thereafter, the crystal grain boundary 17 is formed between the grown crystal portions 21. Therefore, finally, the transparent conductive film 12B (ITO film) formed of significantly large crystals is obtained. For the reasons described above, in the transparent conductive film 12B obtained by low temperature deposition, the number of crystal grain boundaries 17 is fewer than the number of crystal grain boundaries 15 formed in the transparent conductive film 12A. For this reason, it is possible to obtain a transparent conductive film of high quality in which influence of grain boundary scattering is limited to a minimum.

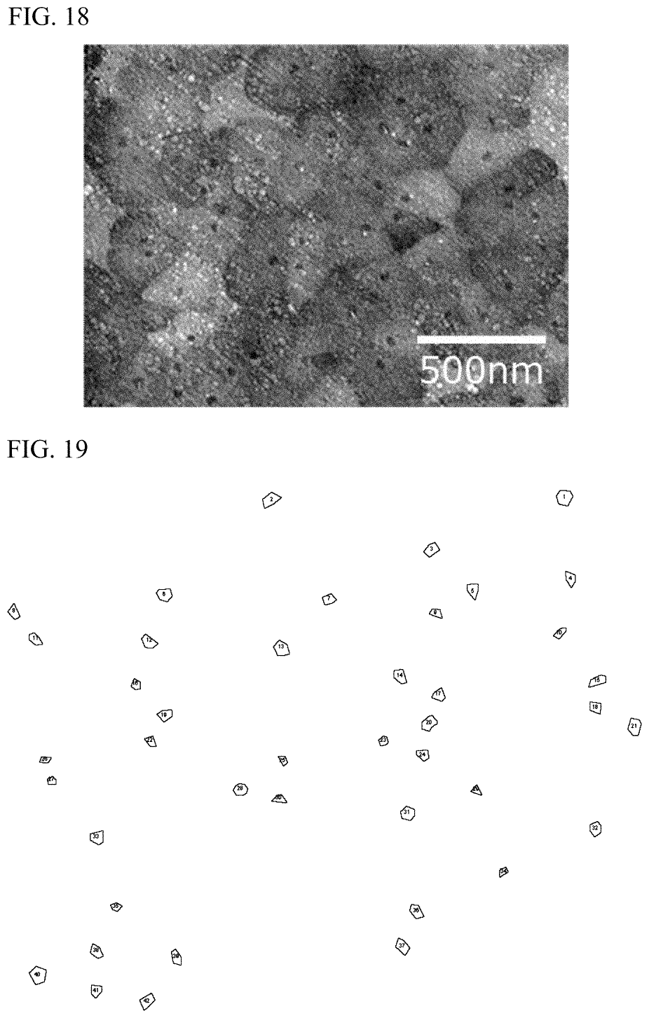

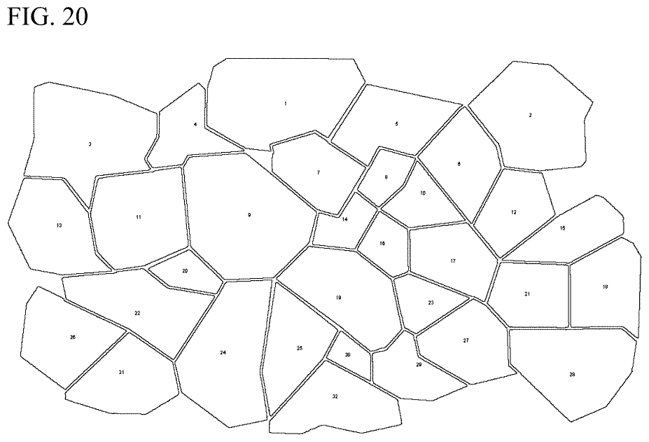

Next, a more specific structure of the above-described transparent conductive film 12B will be described with reference to FIGS. 18 to 20. FIG. 18 is a TEM image of a transparent conductive film (pre-deposition temperature: −16° C.). FIG. 19 is a view obtained by image processing the TEM image shown in FIG. 18 and is a view showing crystal nuclei remaining in the transparent conductive film. FIG. 20 is a view corresponding to outer contours of the crystal portions created on the basis of the TEM image shown in FIG. 18.

FIG. 19 is created by using image processing software (ImageJ), and a plurality of dot-like objects (polygonal shapes) shown in FIG. 19 correspond to crystal nuclei of the transparent conductive film (pre-deposition temperature: −16° C.) shown in FIG. 18. Since 42 crystal nuclei are observed in FIG. 18, the same number of dot-like objects is shown also in FIG. 19.

Further, when each area of the 42 crystal nuclei (dot-like objects shown in FIG. 19) was calculated and each size (size) of the crystal nuclei was measured using the above-described image processing software, the maximum size was 42 nm, the minimum size was 21 nm, and the average size was 30 nm.

Here, a definition of the size (size) of the crystal nucleus will be described. First, an area is calculated for each of the crystal nuclei, and a diameter of a circle having an area (πr²) corresponding to the calculated area is calculated. In the present embodiment, the calculated diameter is defined as a size (size) of the crystal nucleus. Therefore, from the above results, the size of the crystal nucleus can be defined as approximately 21 nm to 42 nm.

From an observation range of 1.23 μm² in the TEM image shown in FIG. 18, it is observed that the number of crystal nuclei is 23, and as an example, the density of the crystal nuclei is approximately 18.76 crystal nuclei/μm².

FIG. 20 shows an outer diameter line corresponding to an outer contour of the crystal portion, and it is created by drawing a line along the outer contour of the crystal portion. In FIG. 20, since 32 crystal portions are observed, the same number of polygonal objects is shown also in FIG. 20.

Further, when each area of the 32 crystal portions (the polygonal objects shown in FIG. 20) was calculated and a size (size) of the crystal portion was measured using the above-described image processing software, a maximum size was 362 nm, a minimum size was 112 nm, and an average size was 236 nm. Here, the size (size) of the crystal portion is defined similarly to the definition of the size of the crystal nucleus described above. That is, an area is calculated for each of the crystal portions, a diameter of a circle having an area (πr²) corresponding to the calculated area is calculated, and the calculated diameter is defined as a size (size) of the crystal portion. Therefore, from the above-described result, a size of the crystal portion can be defined as approximately 112 nm to 362 nm.

While preferred embodiments of the invention have been described and shown above, it should be understood that these are exemplary of the invention and are not to be considered as limiting. Additions, omissions, substitutions, and other modifications can be made without departing from the scope of the invention. Accordingly, the invention is not to be considered as being limited by the foregoing description, and is only limited by the scope of the appended claims.

What is claimed is:

1. A substrate with a transparent conductive film, comprising:
a transparent conductive film that is disposed to be in contact with an insulating transparent substrate and includes:
a crystal nucleus that is generated in a surface layer portion of the transparent conductive film;
a crystal portion that is formed by growth from the crystal nucleus positioned in the surface layer portion and encloses the crystal nucleus; and
a crystal grain boundary that is formed between crystal portions due to the crystal portions located at adjacent positions growing until colliding with each other, wherein
the crystal nucleus remains in the surface layer portion in each of the crystal portions.

2. The substrate with a transparent conductive film according to claim 1, wherein a size of the crystal nucleus is 21 nm to 42 nm.

3. The substrate with a transparent conductive film according to claim 1, wherein a size of each of the crystal portions is 112 nm to 362 nm.

4. The substrate with a transparent conductive film according to claim 1, wherein the crystal grain boundary has a linear shape forming an outer shape of each of the crystal portions.
